(19) United States
(12) Patent Application Publication
(10) Pub. No.: US 2026/0165136 A1
(43) Pub. Date: Jun. 11, 2026

(54) Semiconductor Device and Method of Forming Openings in Blank Area to Reduce Wafer Warpage

(71) Applicant: STATS ChipPAC Pte. Ltd., Singapore (SG)

(72) Inventors: Jian Zuo, Singapore (SG); Beng Yee Teh, Singapore (SG); Lee Sun Lim, Singapore (SG)

(73) Assignee: STATS ChipPAC Pte. Ltd., Singapore (SG)

(21) Appl. No.: 18/975,852

(22) Filed: Dec. 10, 2024

(51) Int. Cl. H01L 23/00

(52) U.S. Cl. CPC H10W 42/121; H10W 70/09; H10W 70/60

(57) ABSTRACT

A semiconductor device has a substrate where a portion of the substrate constitutes a blank area absent a conductive layer. A first insulating layer is formed over the blank area. A second insulating layer is formed over the first insulating layer. A plurality of first openings is formed in the first insulating layer over the blank area. A plurality of second openings is formed in the second insulating layer over the blank area. The first openings and second openings can be arranged in parallel rows, oval, circular, serpentine, random, or other geometric shape. A portion of the second openings is aligned with the first openings. A portion of the second openings is offset with respect to the first openings. A third insulating layer, arranged as a plurality of islands of insulating material, can be formed over the substrate within the blank area.

### FIELD OF THE INVENTION

The present invention relates in general to semiconductor devices and, more particularly, to a semiconductor device and method of forming openings in a blank area to reduce wafer warpage.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor die are typically formed as a semiconductor wafer. Each semiconductor die may require a blank area over a die sensitive area. A blank area is an area of the wafer that is absent overlying metal layers, such as redistribution layers (RDL) or other electrical interconnect. A die sensitive area can be a radio frequency (RF) transceiver zone, for example, in an embedded wafer level ball grid array (eWLB) or wafer level chip scale package (wLCSP). The blank area reduces noise and interference for the die sensitive area. The blank area, absent overlying metal layer, is less rigid, with less structural support, and leads to an imbalance of package metal coverage. The blank area can cause stress and warpage of the semiconductor wafer. The stress and warpage can result in cracking of the conductive and insulating layers, damage to the active area, and lower yield in the manufacturing process.

### BRIEF DESCRIPTION OF THE DRAWINGS

FIGS. 1a-1b illustrate a semiconductor wafer with a plurality of semiconductor die separated by a saw street;

FIGS. 2a-2r illustrate a process of forming openings in a blank area of a semiconductor wafer to reduce warpage;

FIGS. 3a-3d illustrate various patterns for the openings in the blank area of the semiconductor wafer;

FIGS. 4a-4e illustrate a process of forming islands of insulating material and openings in a blank area of a semiconductor wafer to reduce warpage;

FIGS. 5a-5c illustrate various patterns for the islands of insulating material and openings in the blank area of the semiconductor wafer;

FIG. 6 illustrates another embodiment of forming openings in a blank area of a semiconductor wafer to reduce warpage;

FIG. 7 illustrates yet another embodiment of forming openings in a blank area of a semiconductor wafer to reduce warpage; and

FIG. 8 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

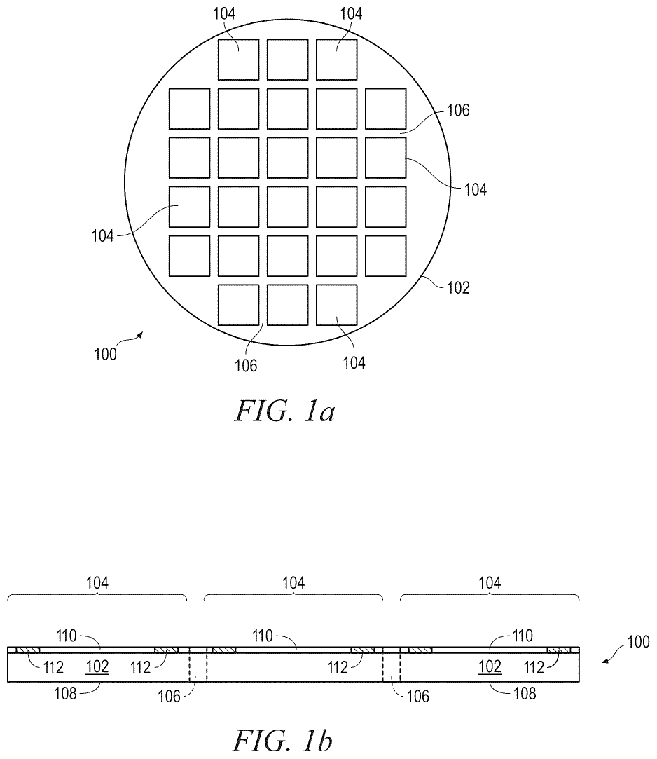

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular or any other geometric shape.

FIG. 1b shows a cross-sectional view of a portion of semiconductor wafer 100. Each semiconductor die 104 has a back or non-active surface 108 and an active layer 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over or within active layer 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits in active layer 110.

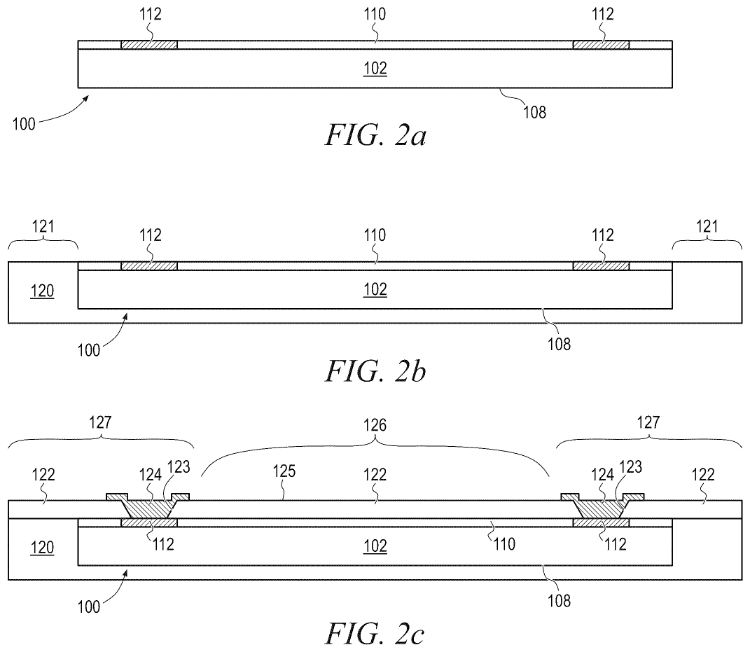

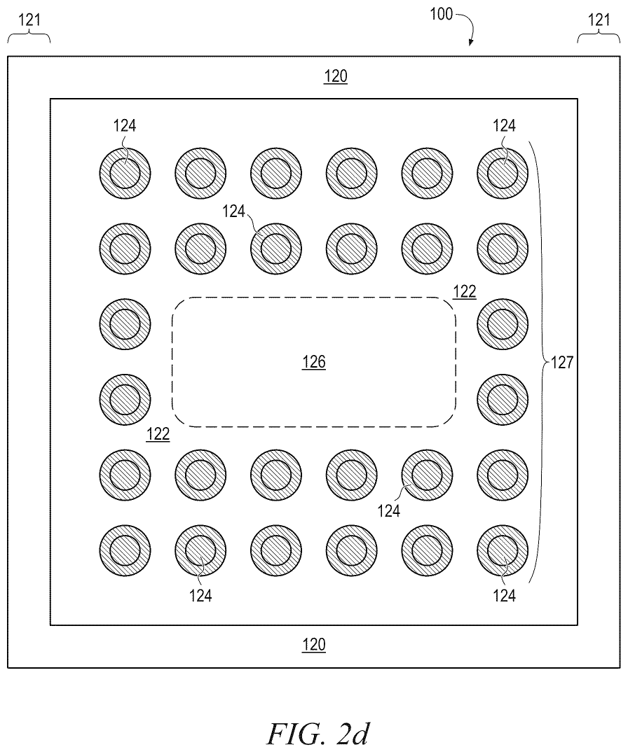

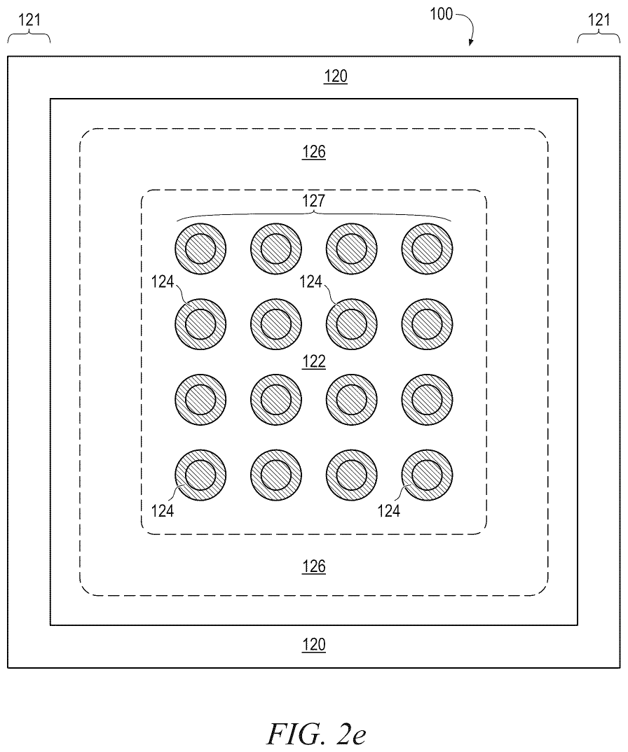

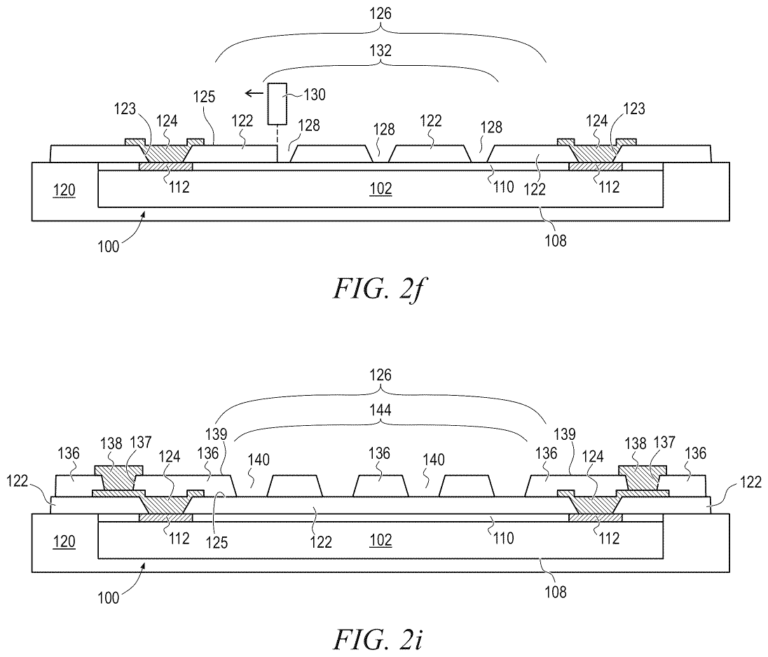

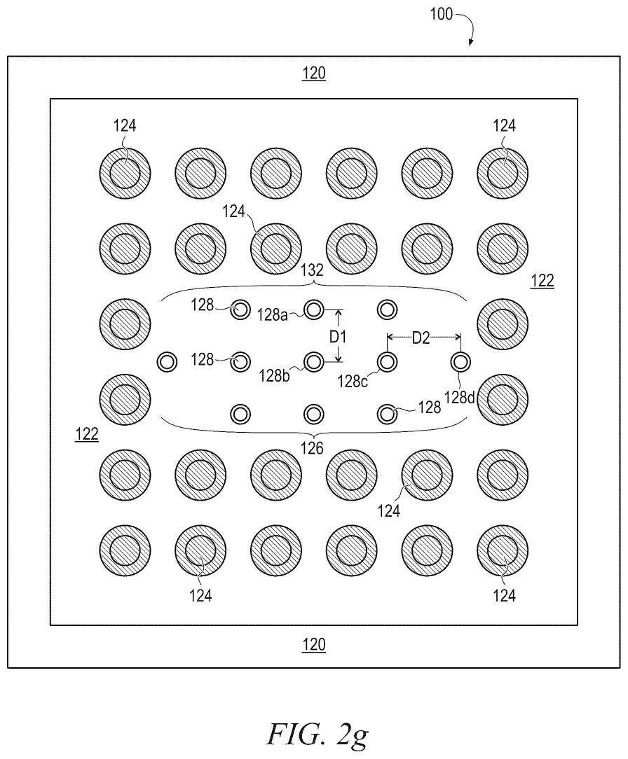

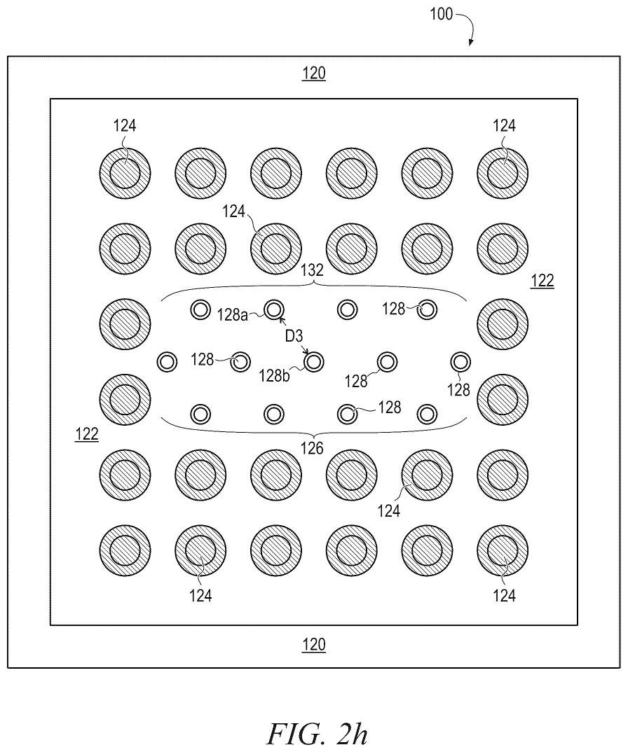

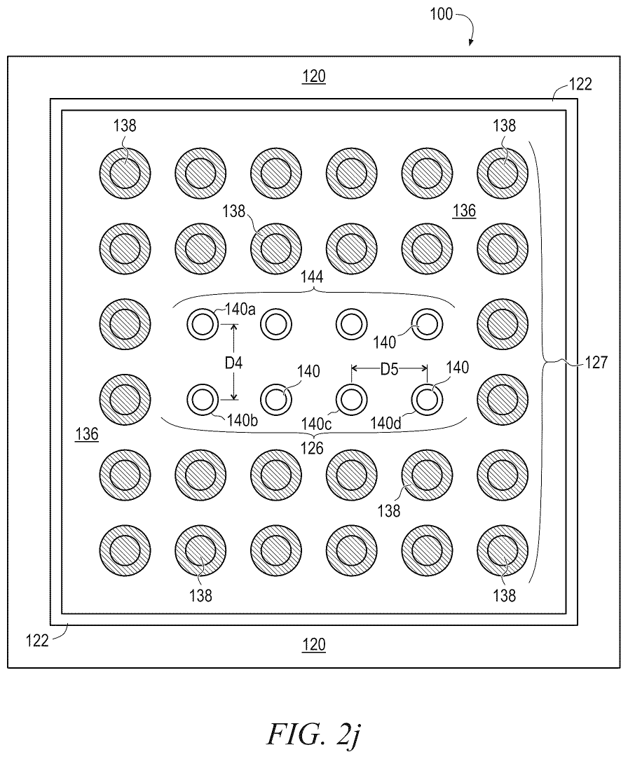

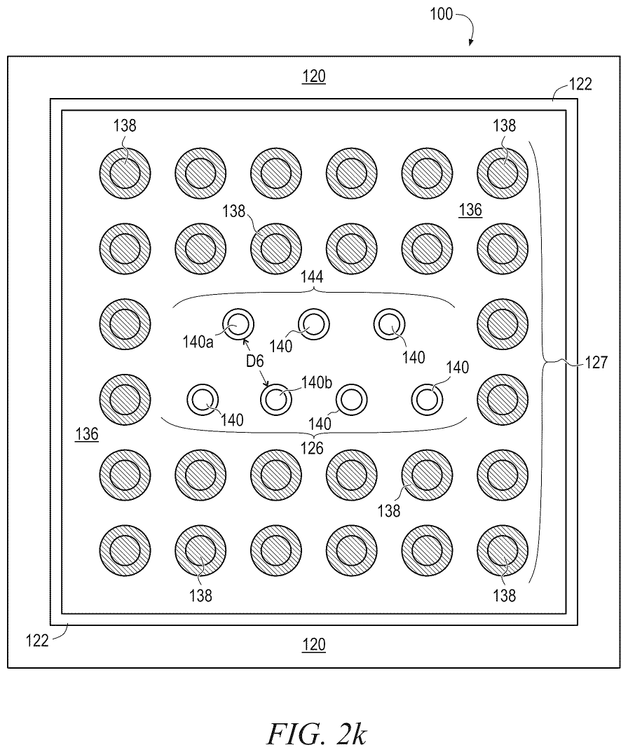

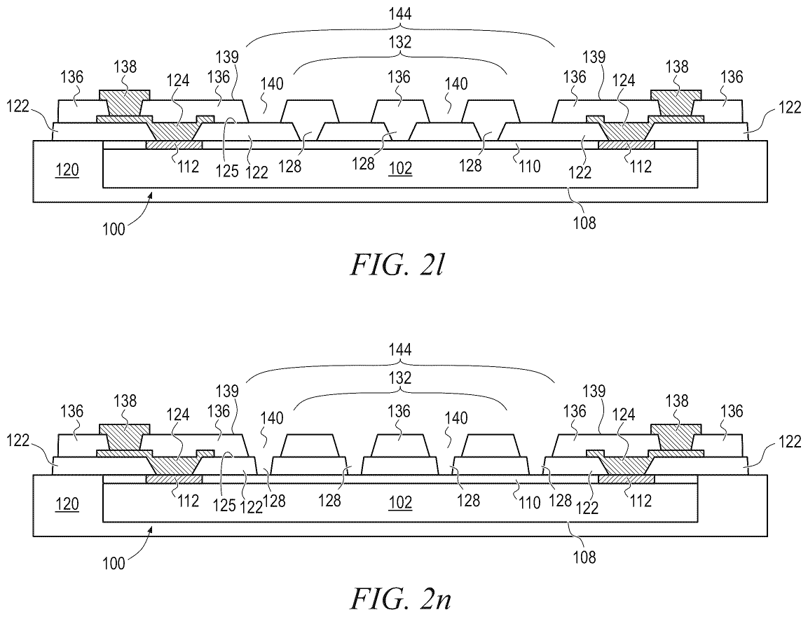

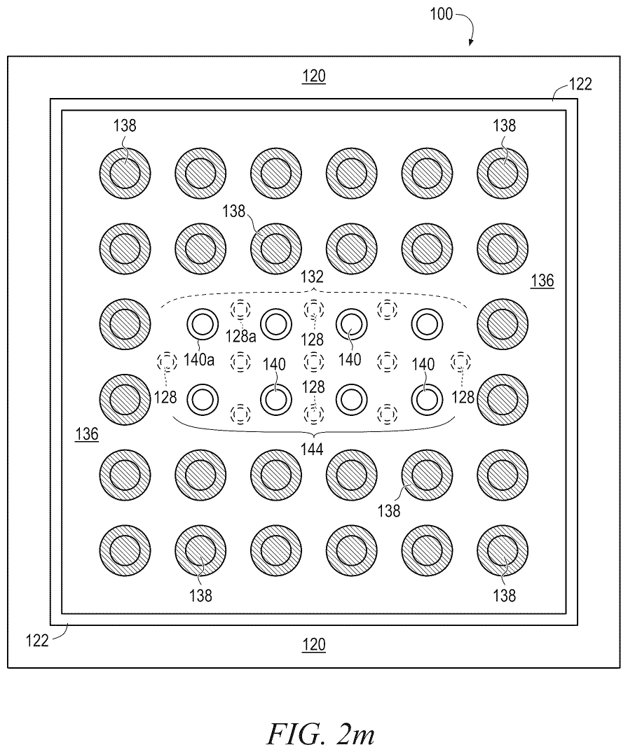

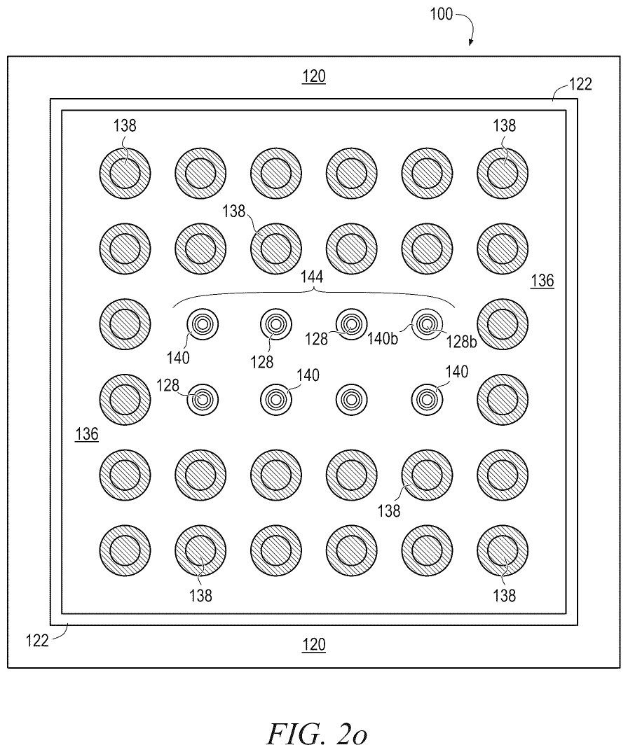

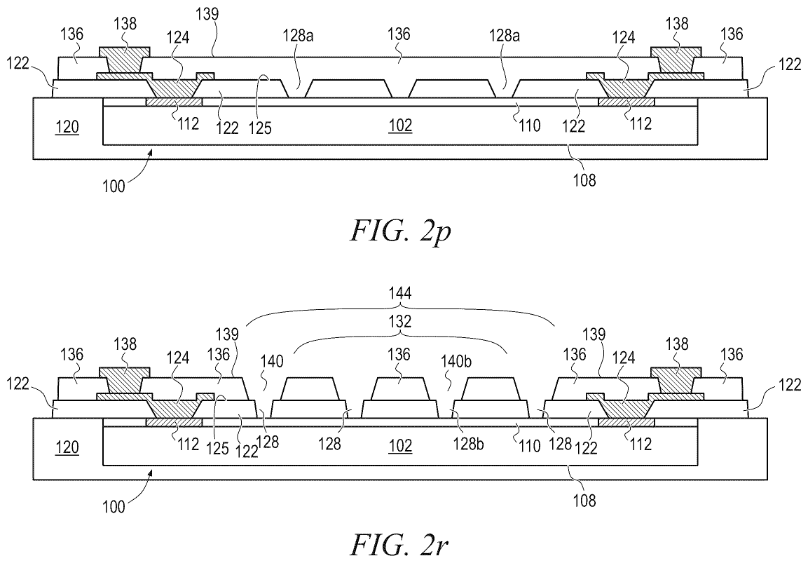

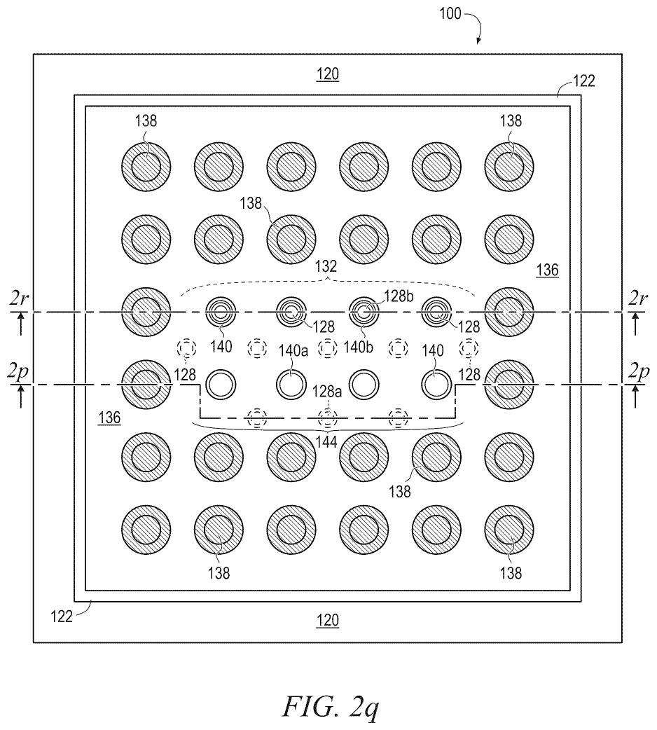

FIGS. 2a-2r illustrate a process of forming a semiconductor wafer with reduced wafer warpage. FIG. 2a shows a cross-sectional view of a portion of semiconductor wafer 100 with base semiconductor material 102, active layer 110, and conductive layer 112. For example, FIG. 2a may represent one semiconductor die 104.

In FIG. 2b, an encapsulant 120 is deposited over back surface 108 of semiconductor wafer 100. Encapsulant 120 can be polymer composite material, such as epoxy resin with filler, epoxy acrylate with filler, or polymer with proper filler. Encapsulant 120 is non-conductive, provides structural support, and environmentally protects the semiconductor device from external elements and contaminants. Encapsulant 120 extends around semiconductor wafer 100, outside a footprint of the wafer, into area 121. Any portion of encapsulant 120 on active surface 110 is removed.

In FIG. 2c, an insulating or passivation layer 122 is formed over active surface 110 and encapsulant 120 in area 121 using PVD, CVD, printing, lamination, spin coating, spray coating, sintering or thermal oxidation. Insulating layer 122 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. A portion of insulating layer 122 is removed by an etching process or laser direct ablation (LDA) to form one or more openings 123 extending down to conductive layer 112. The locations of openings 123 are selected to align with conductive layer 112. A conductive layer 124 is formed over insulating layer 122 and into opening 123 to contact conductive layer 112 using PVD, CVD, electrolytic plating, electroless plating process, or other suitable metal deposition process. Conductive layer 124 can be one or more layers of Al, Cu, Sn, Ni, Au, Ag, or other suitable electrically conductive material. Conductive layer 124 provides horizontal electrical interconnect across and vertical electrical interconnect through semiconductor wafer 100, such as redistribution layer(s) (RDL). Conductive layer 124 extends from conductive layer 112, up the sidewalls of opening 123 and over surface 125 of insulating layer 122. Portions of conductive layer 124 can be electrically common or electrically isolated depending on the design and function of semiconductor die 104 within semiconductor wafer 100 and other electrical components.

Semiconductor wafer 100 contains a blank area or non-conductive area 126. A blank area 126 is an area of semiconductor wafer 100 that is absent an electrical interconnect structure. Whereas the non-blank area 127 (outside blank area 126) contains a conductive structure, such as conductive layer 124, blank area 126 has no overlying electrical interconnect. FIG. 2d is a top view of semiconductor wafer 100, including encapsulant 120, insulating layer 122, conductive layer 124, blank area 126, and non-blank area 127. Blank area 126 can be located at a central portion of semiconductor wafer 100. Alternatively, blank area 126 can be located around a periphery of semiconductor wafer 100, with conductive layer 124 in non-blank area 127 located more central to the semiconductor wafer, as shown in FIG. 2e. Since blank area 126 is absent RDL or other forms of electrical interconnect, the area is less rigid, more flexible, and subject to a higher stress and opportunity for warping.

Returning to FIG. 2c, a portion of insulating layer 122 is removed by an etching process or LDA, e.g., using laser 130, to form one or more openings 128 within blank area 126, as shown in FIG. 2f. Openings 128 can be circular, oval, rectangular, pyramid, or any other geometric shape. Openings 128 are arranged in a pattern 132 within blank area 126 and extend partially or completely through insulating layer 122. FIG. 2g is a top view of semiconductor wafer 100 including encapsulant 120, insulating layer 122, conductive layer 124, blank area 126, and openings 128 arranged in pattern 132. In one embodiment, pattern 132 includes a plurality of parallel rows of openings 128, each with a diameter or width of 20.0 micrometers (mm) or more. The distance D1 between a center of opening 128a and a center of opening 128b is 50.0 mm or more. The distance D2 between a center of opening 128c and a center of opening 128d is 50.0 mm or more. In another embodiment, pattern 132 includes a plurality of parallel rows of openings 128, each offset with respect to an adjacent row, as shown in FIG. 2h. In this case, opening 128a is offset with respect to opening 128b and separated by D3 of 50.0 mm or more. Alternatively, openings 128 have a 20.0 mm diameter with 30.0 mm spacing between openings.

In FIG. 2i, an insulating or passivation layer 136 is formed over insulating layer 122, including those regions within blank area 126 over active surface 110 and encapsulant 120 in area 121 using PVD, CVD, printing, lamination, spin coating, spray coating, sintering or thermal oxidation. Insulating layer 136 contains one or more layers of SiO2, Si3N4, SiON, Ta2O5, Al2O3, polyimide, BCB, PBO, and other material having similar insulating and structural properties. A portion of insulating layer 136 is removed by an etching process or LDA to form one or more openings 137 extending through insulating layer 136 down to conductive layer 124. The locations of openings 137 are selected to align with conductive layer 124. A conductive layer 138 is formed over insulating layer 136 and into openings 137 to contact conductive layer 124 using PVD, CVD, electrolytic plating, electroless plating process, or other suitable metal deposition process. Conductive layer 138 can be one or more layers of Al, Cu, Sn, Ni, Au, Ag, or other suitable electrically conductive material. Conductive layer 138 provides horizontal electrical interconnect across and vertical electrical interconnect through semiconductor wafer 100, such as an RDL. Conductive layer 138 extends from conductive layer 124, up the sidewalls of openings 137 and over surface 139 of insulating layer 136. Portions of conductive layer 138 can be electrically common or electrically isolated depending on the design and function of semiconductor die 104 within semiconductor wafer 100 and other electrical components.

A portion of insulating layer 136 is removed by an etching process or LDA, similar to FIG. 2f, to form one or more openings 140 within blank area 126. Openings 140 can be circular, oval, rectangular, pyramid, or any other geometric shape. Openings 140 are arranged in a pattern 144 and extend partially or completely through insulating layer 136. FIG. 2j is a top view of semiconductor wafer 100 including encapsulant 120, insulating layer 136, conductive layer 138, blank area 126, non-blank area 127, and openings 140 arranged in pattern 144. In one embodiment, pattern 144 includes a plurality of parallel rows of openings 140, each with a diameter or width of 30.0 mm or more. The distance D4 between a center of opening 140a and a center of opening 140b is 60.0 mm or more. The distance D5 between a center of opening 140c and a center of opening 140d is 60.0 mm or more. In another embodiment, pattern 144 includes a plurality of parallel rows of openings 140, each offset with respect to an adjacent row, as shown in FIG. 2k. In this case, opening 140a is offset with respect to opening 140b and separated by D6 of 60.0 mm or more. Alternatively, openings 140 have a 30.0 mm diameter with 30.0 mm spacing between openings.

Given the above examples of openings 128 in insulating layer 122 and openings 144 in insulating layer 136, all within blank area 126, the possible variations are numerous. FIG. 2l shows openings 140 offset with respect to openings 128 and insulating layer 136 fillings openings 128. FIG. 2m is a top view corresponding to FIG. 2l with openings 140 offset with respect to openings 128. For example, opening 140a is offset with respect to opening 128a. That is, a footprint of opening 128b is wholly outside a footprint of opening 140b. FIG. 2n shows openings 140 aligned with openings 128. FIG. 2o is a top view corresponding to FIG. 2n with openings 140 aligned with openings 128. For example, opening 140b is aligned with opening 128b. That is, a footprint of opening 128b is wholly contained with a footprint of opening 140b. In the case of FIGS. 2l-2n, the values for D1-D6 can be 70.0 mm or more.

FIG. 2p shows some openings 140 offset with respect to openings 128. FIG. 2q is a top view corresponding to FIG. 2p and in particular line 2p-2p showing some opening0s 140 offset with respect to openings 128. For example, opening 140a is offset with respect to opening 128a. In the same wafer, FIG. 2r shows other openings 140 aligned with openings 128. In FIG. 2q, line 2r-2r showing other openings 140 aligned with openings 128, in accordance with FIG. 2r. For example, opening 140b is aligned with opening 128b.

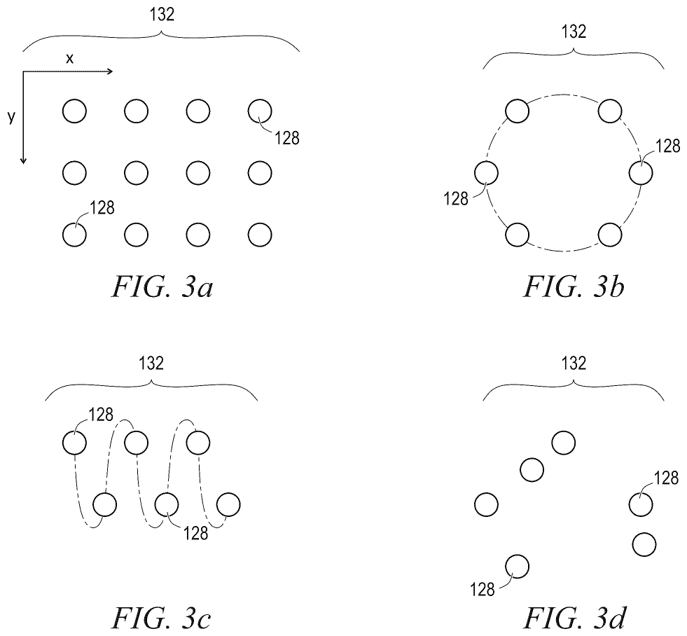

Accordingly, within pattern 132, openings 128 can be arranged in parallel rows, in the x and y directions, as in FIG. 3a. Openings 128 in pattern 132 can be arranged in other shapes, such as circular, oval, serpentine, zigzag, and geometrical patterns, as in FIGS. 3b-3c. Pattern 132 can randomize openings 128, as in FIG. 3d. Likewise, within pattern 144, openings 140 can be arranged in parallel rows, in the x and y directions. Openings 140 in pattern 144 can be arranged in other shapes, such as circular, oval, serpentine, zigzag, and geometrical patterns, similar to FIGS. 3b-3c. Pattern 144 can randomize openings 140, similar to FIG. 3d. Pattern 144 can be arranged in any of the above geometrical patterns, while pattern 132 is arranged in the same or different one of the above geometrical patterns. Openings 144, in its chosen geometrical pattern, can be offset with respect to openings 128, in its chosen geometrical pattern. Openings 144, in its chosen geometrical pattern, can be aligned with openings 128, in its chosen geometrical pattern 144. Some openings 144, in its chosen geometrical pattern, can be offset with respect to openings 128, in its chosen geometrical pattern, while other openings 144 can be aligned with openings 128, all within their respective geometrical pattern.

Dummy openings 128 in insulating layer 122 and dummy openings 140 in insulating layer 136, all within blank area 126, serve to relieve stress and prevent or reduce warpage. Dummy openings 128 in insulating layer 122 and dummy openings 140 in insulating layer 136, all within blank area 126, have deminimus impact on the electrical properties of the semiconductor package.

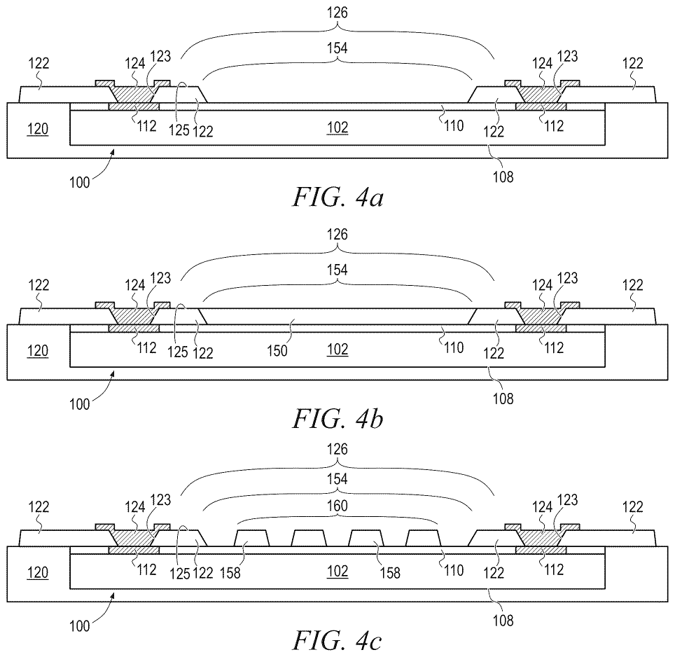

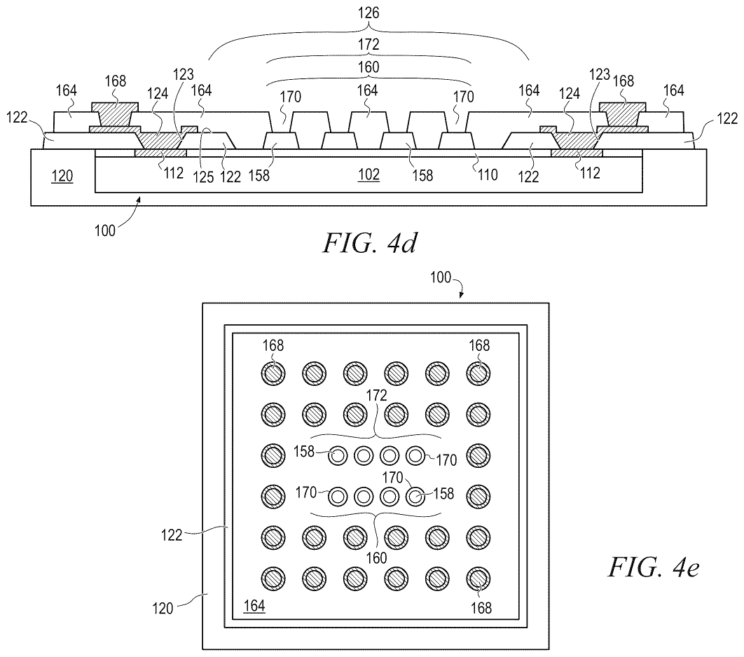

In another embodiment, continuing from FIG. 2c, a portion of insulating layer 122 is removed by etching or LDA, similar to FIG. 2f, to form large opening 154 within blank area 126, as shown in FIG. 4a. Components having a similar function are assigned the same reference number. In FIG. 4b, an insulating or passivation layer 150 is formed within blank area 126 over active layer 110 using PVD, CVD, printing, lamination, spin coating, spray coating, sintering or thermal oxidation. Insulating layer 150 contains one or more layers of SiO2, Si3N4, SiON, Ta2O5, Al2O3, polyimide, BCB, PBO, and other material having similar insulating and structural properties. In FIG. 4c, a portion of insulating layer 150 is removed by an etching process or LDA to form islands of insulating material 158. The islands of insulating material 158 can be arranged in a pattern 160, similar to pattern 132. That is, pattern 160 may include parallel rows, in the x and y directions, of islands of insulating material, similar to FIG. 3a. Pattern 160 can be arranged in other shapes, such as circular, oval, serpentine, zigzag, and geometrical patterns, similar to FIGS. 3b-3c. Pattern 160 can randomize islands of insulating material 158, similar to FIG. 3d. In FIG. 4d, insulating layer 164 and conductive layer 168 are formed, as described for insulating layer 136 and conductive layer 138 in FIG. 2i.

A portion of insulating layer 164 is removed by an etching process or LDA, similar to FIG. 2f, to form one or more openings 170 within blank area 126. Openings 170 are arranged in a pattern 172 and extend partially or completely through insulating layer 164. FIG. 4e is a top view of semiconductor wafer 100 including encapsulant 120, islands of insulating material 158 arranged in pattern 160, insulating layer 164, conductive layer 168, blank area 126, and openings 170 arranged in pattern 172. In one embodiment, pattern 172 includes a plurality of parallel rows of openings 170, although pattern 172 can have any arrangement as described for pattern 132 and pattern 144.

Dummy islands of insulating material 158 and dummy openings 170 in insulating layer 164, all within blank area 126, serve to relieve stress and prevent or reduce warpage. Dummy islands of insulating material 158 and dummy openings 170 in insulating layer 164, all within blank area 126, have deminimus impact on the electrical properties of the semiconductor package.

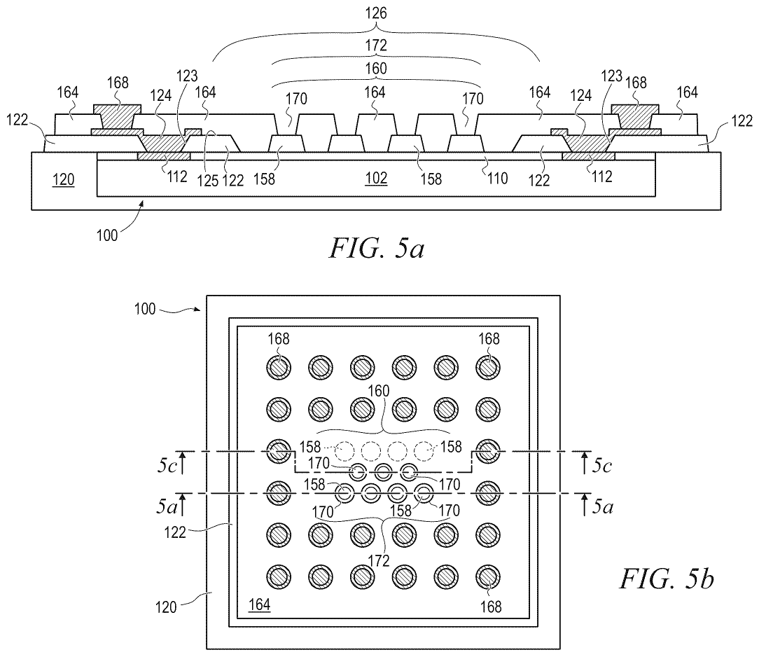

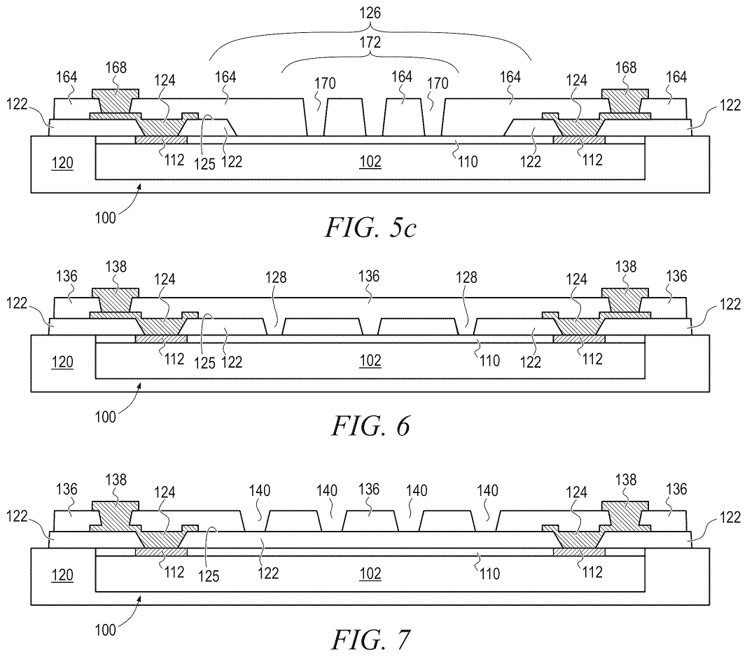

FIG. 5a illustrates openings 170 within pattern 172 aligned with islands of insulating material 158, as arranged in pattern 160. FIG. 5b is a top view showing openings 170 aligned with islands of insulating material 158 along line 5a-5a. FIG. 5c illustrates openings 170 within pattern 172 offset with respect to islands of insulating material 158, as arranged in pattern 160. FIG. 5c shows openings 170 offset with respect to islands of insulating material 158 along line 5c-5c.

Given the above examples of islands of insulating material 158 and openings 170 in insulating layer 164, all within blank area 126, the possible variations are numerous. Openings 170 can be aligned with islands of insulating material 158. Openings 170 can be offset with respect to islands of insulating material 158. Some openings 170 can be aligned with islands of insulating material 158, while other openings 170 can be offset with respect to islands of insulating material 158.

Accordingly, islands of insulating material 158 within pattern 160, as well as openings 170 within pattern 172, can be arranged in a variety of patterns, similar to FIGS. 2a-2r and 3a-3d.

FIG. 6 illustrates openings 128 in insulating layer 122 arranged in pattern 132 with no openings in insulating layer 136. FIG. 7 illustrates openings 140 in insulating layer 136 arranged in pattern 144 with no openings in insulating layer 122.

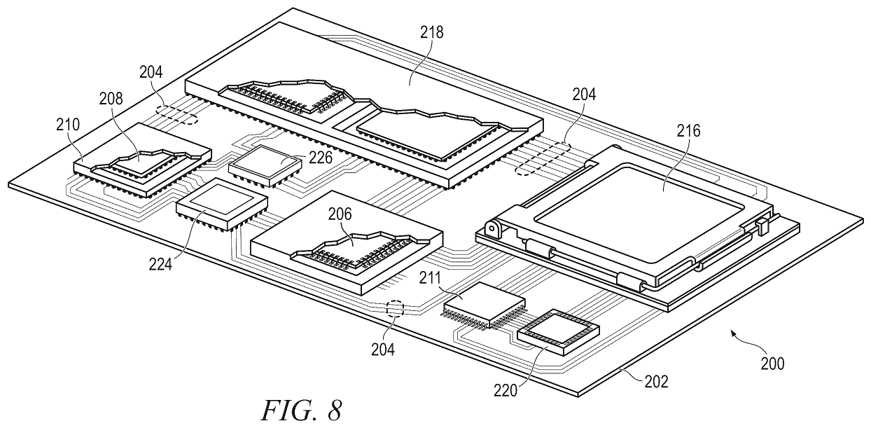

FIG. 8 illustrates electrical device 400 having a chip carrier substrate or PCB 402 with a plurality of semiconductor packages disposed on a surface of PCB 402. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 8, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate, wherein a portion of the substrate constitutes a blank area absent a conductive layer;
a first insulating layer formed over the blank area; and
a plurality of first openings formed in the first insulating layer over the blank area.

2. The semiconductor device of claim 1, further including a second insulating layer formed over the first insulating layer.

3. The semiconductor device of claim 2, further including a plurality of second openings formed in the second insulating layer over the blank area.

4. The semiconductor device of claim 3, wherein a portion of the second openings is aligned with the first openings.

5. The semiconductor device of claim 3, wherein a portion of the second openings is offset with respect to the first openings.

6. The semiconductor device of claim 1, further including a third insulating layer formed over the substrate within the blank area.

7. A semiconductor device, comprising:
a substrate including a blank area absent a conductive layer; and
a first insulating layer formed over the blank area with a plurality of first openings formed in the first insulating layer over the blank area.

8. The semiconductor device of claim 7, further including a second insulating layer formed over the first insulating layer.

9. The semiconductor device of claim 8, further including a plurality of second openings formed in the second insulating layer over the blank area.

10. The semiconductor device of claim 9, wherein a portion of the second openings is aligned with the first openings.

11. The semiconductor device of claim 9, wherein a portion of the second openings is offset with respect to the first openings.

12. The semiconductor device of claim 7, further including a third insulating layer formed over the substrate within the blank area.

13. The semiconductor device of claim 12, wherein the third insulating layer is arranged as a plurality of islands of insulating material.

14. A method of making a semiconductor device, comprising:
providing a substrate, wherein a portion of the substrate constitutes a blank area absent a conductive layer;
forming a first insulating layer over the blank area; and
forming a plurality of first openings in the first insulating layer over the blank area.

15. The method of claim 14, further including forming a second insulating layer over the first insulating layer.

16. The method of claim 15, further including forming a plurality of second openings in the second insulating layer over the blank area.

17. The method of claim 16, further including aligning a portion of the second openings with the first openings.

18. The method of claim 16, further including arranging a portion of the second openings offset with respect to the first openings.

19. The method of claim 14, further including forming a third insulating layer over the substrate within the blank area.

20. A method of making a semiconductor device, comprising:
providing a substrate including a blank area absent a conductive layer; and
forming a first insulating layer over the blank area with a plurality of first openings formed in the first insulating layer over the blank area.

21. The method of claim 20, further including forming a second insulating layer over the first insulating layer.

22. The method of claim 21, further including forming a plurality of second openings in the second insulating layer over the blank area.

23. The method of claim 22, further including aligning a portion of the second openings with the first openings.

24. The method of claim 22, further including arranging a portion of the second openings offset with respect to the first openings.

25. The method of claim 20, further including forming a third insulating layer over the substrate within the blank area.
